(19) United States
(12) Patent Application Publication
(10) Pub. No.: US 2019/0165720 A1
(43) Pub. Date: May 30, 2019

(54) SOLAR TILE SYSTEM

(71) Applicant: SolaBlock LLC, Easthampton, MA (US)

(72) Inventors: Patrick John Adrian Quinlan, Hadley, MA (US); Jason Michael Laverty, Westfield, MA (US)

(21) Appl. No.: 16/302,013

(22) PCT Filed: May 17, 2017
(86) PCT No.: PCT/US17/33045

§ 371 Date: Nov. 15, 2018

Related U.S. Application Data
(60) Provisional application No. 62/337,651, filed on May 17, 2016.

(51) Int. Cl. H02S 20/25; H02S 40/34; H01L 31/044; H01L 31/048; G09F 3/00

(52) U.S. Cl. CPC H02S 20/25; H02S 40/34; G09F 3/0291; H01L 31/048; H01L 31/044

(57) ABSTRACT

A tile unit can include one or more solar cells for generation of electricity. The photovoltaic-clad tile unit combines the physical protective attributes of a tile with the energy production of solar photovoltaics. Methods for manufacturing, installing, and electrically connecting such photovoltaic-clad tile units are also described. The photovoltaic-clad tile units include a plurality of equal-length wiring channels that permit wired tiles to be installed in different relative positions while still wired to each other. The equal-length wiring channels reduce cost, weight, and installation-time of solar photovoltaic-clad tiles in comparison to other technologies and individual tile-to-tile wiring technologies

### CLAIM OF PRIORITY

This application claims priority to U.S. Patent Provisional Patent Application No. 62/337,651, filed May 17, 2016 which is hereby incorporated by reference in its entirety.

### FIELD

The present invention relates to solar panels and more particularly to photovoltaic-clad tiles for providing solar-energy collection on building exteriors.

### BACKGROUND

Since electricity is an expensive utility, one step towards conservation is to design buildings that reduce demand of electricity purchased from the power grid. One way to reduce the amount of energy required to power a building is to supplement or replace reliance on energy purchased from the power grid by using renewable sources of energy such as solar energy to power the building and devices within the building.

In general, a photovoltaic cell or photocell is an electrical device that converts the energy of light directly into electricity by the photovoltaic effect. One example of using solar energy is the use of photovoltaic arrays on the outer surfaces of buildings and structures, such as the roofs and outer walls of the building or structure. Such photovoltaic arrays can be attached to the building and interconnected after the building is built, thus allowing a building to be retrofitted to use renewable energy.

### SUMMARY OF THE INVENTION

Photovoltaic tile units including one-or-more photovoltaic cells (e.g., solar cells) for generation of electricity. The tiles combine the physical attributes of a tile with the energy production of solar photovoltaics. The tiles are configured to provide easy manufacturing, installing, and electrical connecting.

Photovoltaic-clad tile units can be used to “solarize” residential or commercial building walls, cavity walls, retaining walls, rights-of-way, garden walls, sound walls or any wall or portion of a facade receiving sunlight for a portion of the day. The photovoltaic-clad tile units can also be used to harvest renewable energy from highway sound-walls, bridges, parking structures, railroad rights-of-way, property walls, or any other conventionally-walled location and/or provide solar power to unattended buildings, signs, or off-grid buildings. Additionally, photovoltaic-clad tile units may be used to provide power to critical buildings or shelters that may lose grid-power and/or have a likelihood of damage to conventional roof-mounted solar cells in extreme conditions such as in hurricane-force winds.

In some aspects, a photovoltaic-clad tile unit includes a rigid support structure with a back surface and includes a backer board, the back surface that defines a plurality of equal-length wiring channels in the rigid support structure and a pass-through channel extending across the tile in a straight line, and one or more photovoltaic cells supported by the rigid support structure, and a transparent cover disposed above the one or more photovoltaic cells and configured to be secured to the rigid support structure to provide a protective enclosure that encloses the one or more photovoltaic cells.

Embodiments can include one or more of the following features.

In some embodiments, the plurality of equal-length wiring channels are configured such that adjacent wiring channels between adjacent photovoltaic-clad tile units are provided on an outward facing side of the photovoltaic-clad tile units.

In some embodiments, each of the plurality of equal-length wiring channels extends from a first edge to one of: the first edge, an opposite edge, or a first or second adjacent edge of the backer board.

In some embodiments, the plurality of equal-length wiring channels is a group of seven equal-length wiring channels.

In some embodiments, each of the group of seven equal-length wiring channels extends from a primary entrance in the first edge of the backer board to one of a corresponding seven exits in the edges of the backer board. The group of seven equal-length wiring channels can include: a first channel extending across the tile to a first exit in the opposite edge, a second channel extending to a second exit in the first edge; a third channel extending to a third exit in the first edge, a fourth channel extending to a fourth exit in first adjacent edge, a fifth channel extending to a fifth exit in the second adjacent edge, a sixth channel extending to a sixth exit in the opposite edge, and a seventh channel extending to a seventh exit in the opposite edge, wherein the primary entrance and the first, fourth and fifth exits are located in the approximate center of their respective edges, and wherein the second and third exits are located at a same distance from the primary entrance, and the sixth and seventh exits are located at the same distance from the first exist.

In some embodiments, the pass-through wire follows the same channel as the wires conducting electrical current from a tile to adjacent tiles.

In some embodiments, the tile further includes an adhesive layer disposed on the back surface of the tile, the adhesive layer configured to secure the photovoltaic-clad tile unit to a structure.

In some embodiments, the photovoltaic tile unit further includes a pass though wire adhered to the back surface of the backer board in one of the plurality of equal-length wiring channels or the pass through channel, the pass though wire electrically isolated from the one or more PV cells.

In some embodiments, the rigid support structure includes an input opening and an output opening, the opening providing an electrical connection to the one or more photovoltaic cells.

In some embodiments, the photovoltaic tile unit further includes a power-conductor wire adhered to the back surface of the backer board in one of the plurality of equal-length wiring channels or the pass through channel, the power-conductor wire comprising an input wire in electrical connection with the one or more photovoltaic cells via the input opening and an output wire in electrical connection with the one or more photovoltaic cells via the output opening.

In some embodiments, the back surface defines a cavity between the input and output opening, the cavity sized and positioned to house a bypass diode.

In some embodiments, the back surface defines a cutout sized and positioned to house a connector.

In some embodiments, the backer board includes alignment devices that are raised from the surface of the backer board.

In some embodiments, the photovoltaic unit further includes an opaque removable label adhered to an outer surface of the cover. In some embodiments, the label includes a pre-printed label made of a dissolvable material. In some embodiments, the label includes a first indicator indicative of the location of the positive terminal and a second indicator indicative of the location of the negative terminal.

In some embodiments, the cover includes a transparent glass or polymeric cover and the cover includes a top surface and sidewalls extending approximately perpendicular to the top surface.

In some embodiments, the photovoltaic-clad tile unit further includes a gasket.

In some embodiments, the photovoltaic-clad tile unit is configured to be electrically connected to other photovoltaic-clad tile units to form a photovoltaic array.

In some embodiments, the backer board includes cement and reinforcing fibers. In some embodiments, backer board includes a Portland cement based core with glass fiber mat reinforcing. In some embodiments, the backer board includes glazed- or unglazed ceramic or porcelain material.

Solar technologies, such as the photovoltaic-clad tile units described below, are designed specifically for structural facades in urban and remote areas to be vandal-resistant, theft resistant, and long-lived. These photovoltaic-clad tile units provide the building blocks to cover a wall or other facade. Solar technologies with these design characteristics can supply electricity to critical loads in unattended or remote locations. The tile units can be affixed and grouted in the traditional manner and the wiring of the photovoltaic cells can be completed afterward on the front, outward facing, sides of the blocks (e.g., on the side of the blocks that includes the photovoltaic cells). The photovoltaic-clad tile units provide the physical protective attributes of a tile unit wall and the energy production of solar electric modules. The material of the tile unit provides the structural support for the solar cells while also providing a thermal sink that mitigates high-temperature-based reductions to performance and reliability. The tile unit also provides strength to allow the solar cells to be better protected from damage, and eliminates the need for expensive metal framework supports for the cells.

One technical advantage of the photovoltaic-clad tile system permits installation of strings of photovoltaic-clad tile units that are sufficiently low weight for flexible installation in various configurations on a wall. One aspect of this technical advantage is a unique form of pre-wiring of the interconnection wiring and the pass-through wiring, where the backer-board of each tile is configured to allow customer choice in the relative positioning from one tile to the next. Pre-wiring of photovoltaic-clad tile units into strings avoids the weight, cost, and labor-requirements associated with connecting individual tiles to each other. For each possible user-designated subsequent tile location, constant-length channels in the backer-board create a corresponding wiring path.

These and other advantages will become apparent from reading the below description of the preferred embodiment with reference to the appended drawings.

### BRIEF DESCRIPTION OF DRAWINGS

FIGS. 1A-1G are examples of various tile orientations.

FIGS. 2A-2G are examples of various tile installations.

FIG. 3 is an illustration of the front-face of a tile.

FIGS. 4A and 4B are illustrations of the back-side of a tile without and with, respectively, electrical wiring.

FIG. 4C is a diagram of the back-side of the tile identifying the connections to adjacent tiles.

FIGS. 5A-5G show each of the paths that pass-through wiring can take through the equal-length channels.

FIGS. 6A-6C are front, rear, and side illustrations, respectively, of the backer board.

FIGS. 7A-7D are schematics of various wiring options for a single tile.

FIGS. 8A-8C are electrical schematics of three different strings of 10 tiles.

FIG. 9 is an illustration of a typical wall.

The figures are selected to fully and completely demonstrate the preferred embodiment of the present invention and are not selected to show all conceivable modifications that would fall within the scope of the claim.

### DETAILED DESCRIPTION

In urban locations, where the roof space of buildings is insufficient for providing significant solar generation, sunlit areas of the facade provide an alternative. Solar technologies, such as the photovoltaic-clad tile units described below, are designed specifically for structural facades in urban and remote areas that are vandal-resistant, theft resistant, and long-lived. These photovoltaic-clad tile units provide the building blocks to cover a wall or other facade. Solar technologies with these design characteristics can also supply electricity to critical loads in unattended or remote locations.

Solar photovoltaic-clad tile units provide the building blocks to cover a building, wall, facade, or other structure capable of producing power. The tile units can be installed in the traditional manner and the wiring of the photovoltaic cells can be completed afterward on the front, outward facing, sides of the blocks (e.g., on the side of the blocks that includes the photovoltaic cells). The photovoltaic-clad tile units provide the physical protective attributes of a tile unit wall and the energy production of solar electric modules. The material of the tile unit provides the structural support for the solar cells while also providing a thermal sink that mitigates high-temperature-based reductions to performance and reliability. The tile unit also provides strength to allow the solar cells to be better protected from damage, and eliminates the need for expensive metal framework supports for the cells.

The photovoltaic-clad tile units described herein are similar to the solar masonry systems described in U.S. Pat. No. 9,059,348, the details of which are herein incorporated by reference in their entity. However, the present photovoltaic-clad tile units do not include a concrete masonry substrate or individual connection points. Additionally, the present photovoltaic-clad tiles units include a wiring technology that enables the photovoltaic-clad tiles units to be applied conventionally to existing walls.

However, the great weight and size of concrete blocks makes continuous wiring of multiple blocks impractical, necessitating interconnections between each block in the field. In contrast, the smaller weight and size of tiles permits them to be pre-wired by the manufacturer in strings of multiple tiles, shipped as a group, then wired as strings of tiles at the construction site. This is a key design feature of the photovoltaic-clad tile units wiring.

One technical advantage of the photovoltaic-clad tile system permits installation of strings of photovoltaic-clad tile units that are low weight and flexible for installation in various configurations on a wall. One aspect of this technical advantage is a unique form of pre-wiring of the interconnection wiring and the pass-through wiring, where the backer-board of each tile is configured to allow customer choice in the positioning from one tile to the next. Pre-wiring of photovoltaic-clad tile units into strings avoids the weight, cost, and labor-requirements associated with connecting individual tiles to each other. For each possible user-designated subsequent tile location, constant-length channels in the backer-board create a corresponding wiring path.

In some instances, the backer board is also constructed to provide sufficient space within each tile to allow a field-splice from one string to the next. In some instances, a central cavity within the backer-board provides the space for splice connectors to be made and cached into the back of the tile.

Wiring the photovoltaic-clad tile units may include 2-conductor wire, where one conductor is for power connections from tile to tile and the other is for pass-through wiring. In some instances, the wiring is constructed and insulated for direct burial applications.

Physical Design

The photovoltaic-clad tile units have a distinct physical and electrical design that distinguishes it from both conventional tile and photovoltaic-clad masonry units. A physical difference is the presence of the photovoltaic components forming the product face, minus the concrete frame and substrate of photovoltaic-clad masonry units. An electrical difference in comparison to photovoltaic-clad masonry units is the absence of the junction boxes. In one example, the photovoltaic cell is a commercially available monocrystalline silicon cell with all electrical connections on the shaded side, with the tile measuring 147 mm (5.8 inches) square; the photovoltaic cell is 125 mm (4.9 inches) square. Grout between tiles in this example is 4.6 mm (0.18 inches) in width.

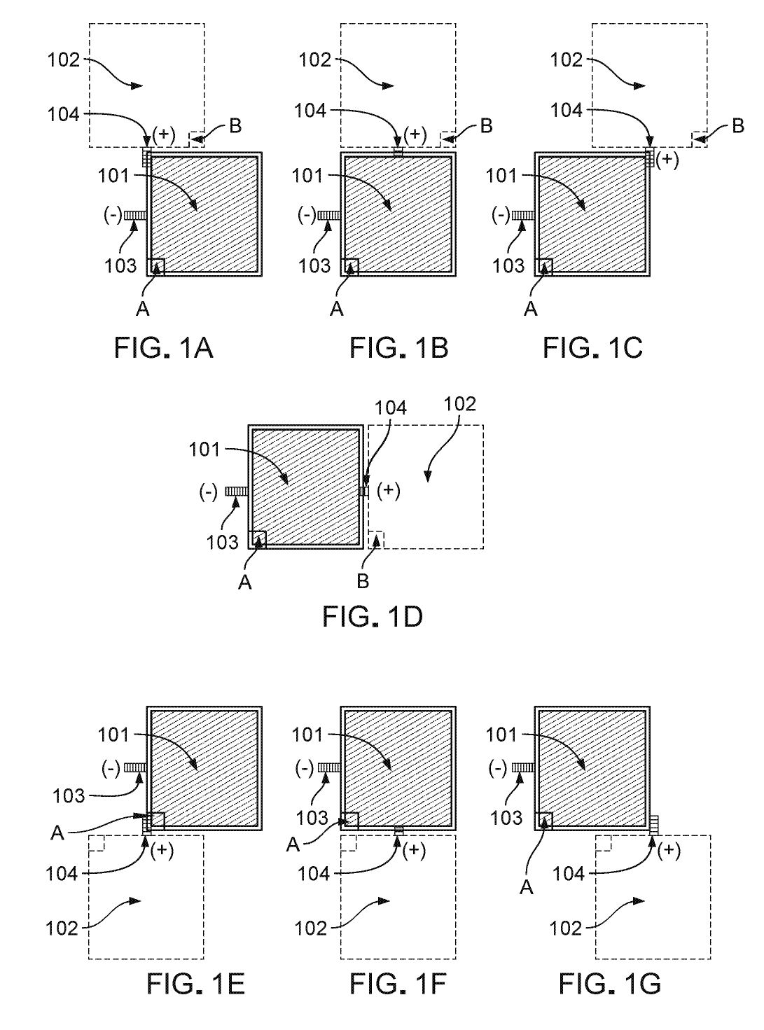

FIGS. 1A-1G are examples of various tile orientation options possible with one embodiment of the present design. The small squares A,B in FIGS. 1A-1G are included to aid in orienting the tiles 101, 102 in the drawing. Tile 101 is the installed tile and tile 102 is the next tile to be installed. Wire 103 is the input lead-wire/pass-through wire and wire 104 is the output lead-wire/pass-through wire leading to tile 102. FIGS. 1A-1G depict the seven possible locations that tile 102 can be installed relative to tile 101. The positions correspond to either a square or offset pattern from course to course.

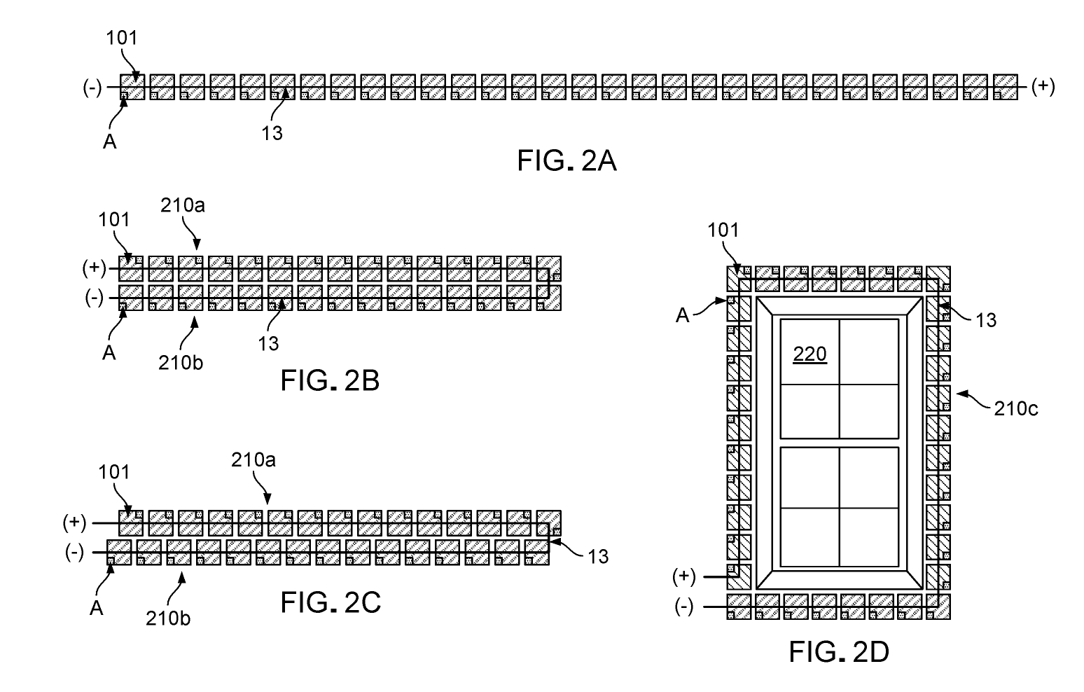

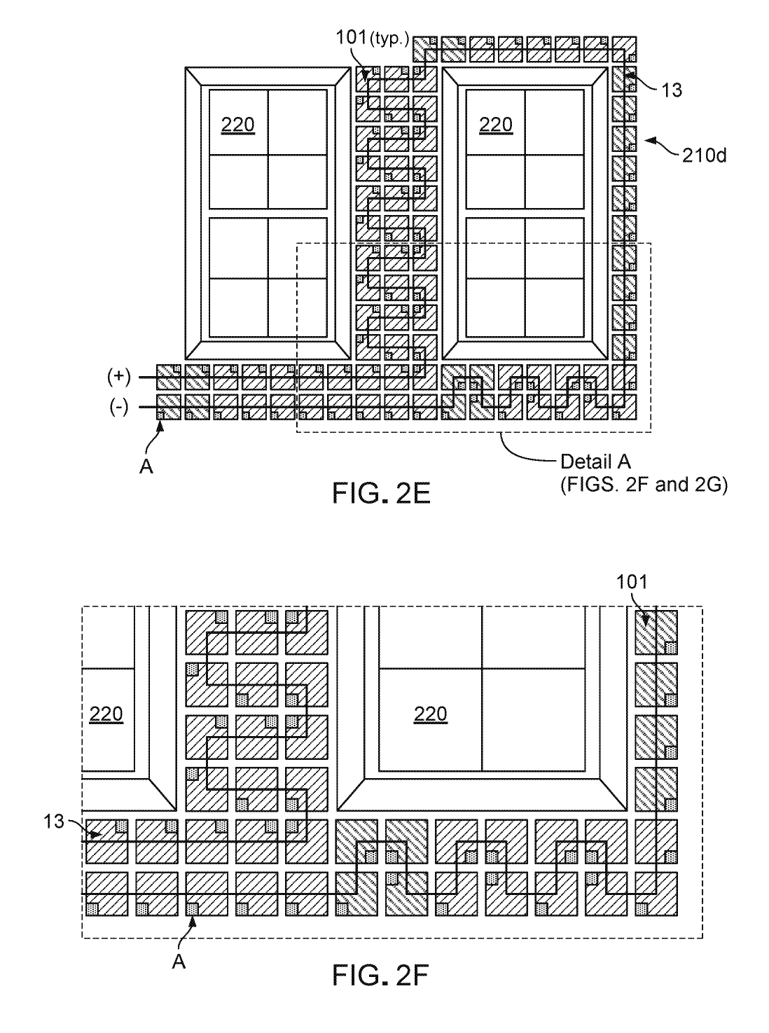

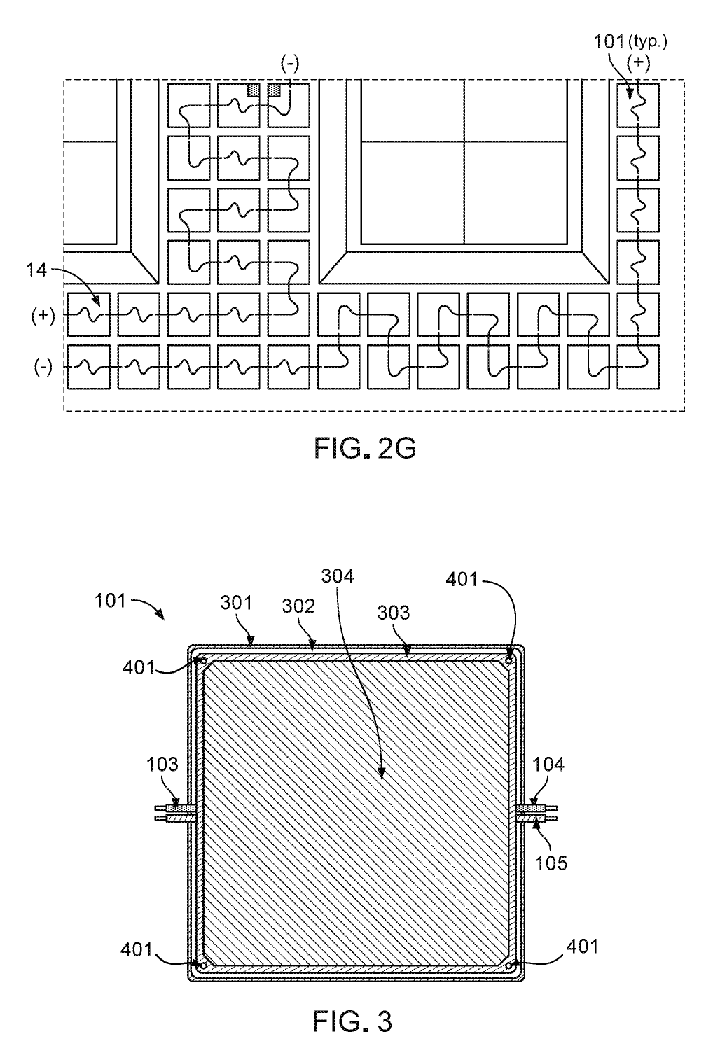

FIGS. 2A-2G are examples of various tile installations possible with the constant-length channels of the present design. FIGS. 2A-2G depict example photovoltaic-clad tile unit installations that take advantage of this design flexibility. The small black squares A are included in the diagrams for orientation purposes. FIG. 2A depicts a linear installation of tiles 101 along a wall using the default internal wiring. FIG. 2B shows the installation of two rows 210a,b of tiles 101 with a grid-style and the wire path 13 traveling in a horizontal direction across a first row 210a, down at the end of the first row 210a into the second row 210b, and across the second row 210b in a horizontal direction. FIG. 2C shows an alternate orientation of the first and second rows 210a,b of tiles 101 with the second row 210b offset horizontally from the first row 210a. FIG. 2D shows an example of wrapping a window 220 with a single string 210c of tiles 101. FIG. 2E shows a string 210d of tiles 101 oriented to fill areas within complex architectural constraints, for example, between two windows 220.

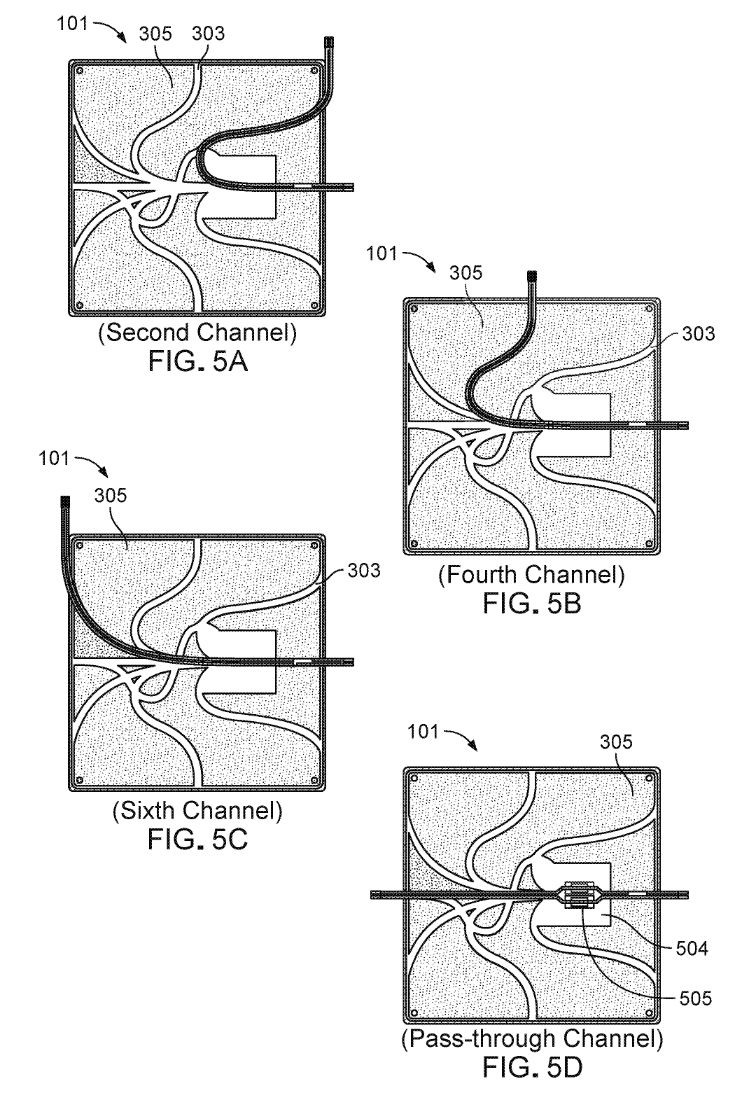

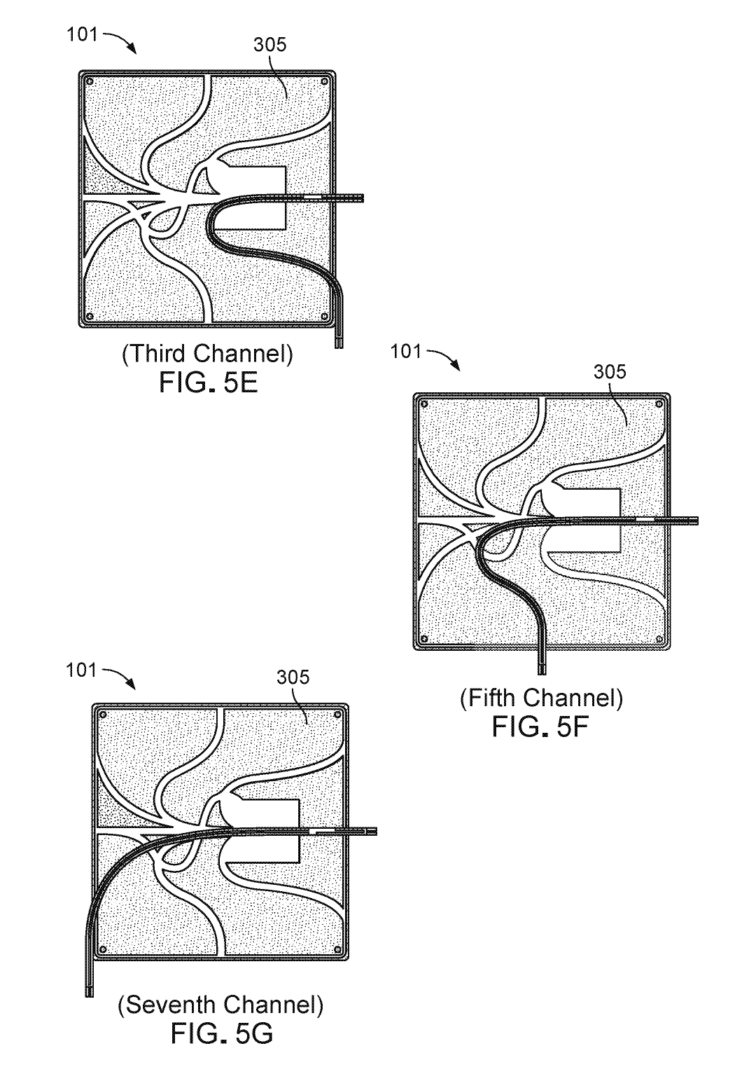

FIG. 2F shows ‘Detail A’ of FIG. 2E. In FIG. 2F, the wiring patch 13 of each individual tile 101 around the windows 202 is shown, along with black squares A on each tile 101 indicating the orientation of the tile 101. FIG. 2G is an illustration of the course taken by an actual wire 14 through the plurality of tiles 101 in Detail A, with the course 14 though each tile 101 being dependent on the orientation of the tile 101 and the connection of the wire 14 to the adjacent tiles 101. This wire path 14 for each tile is show with more detail in FIGS. 5A-G.

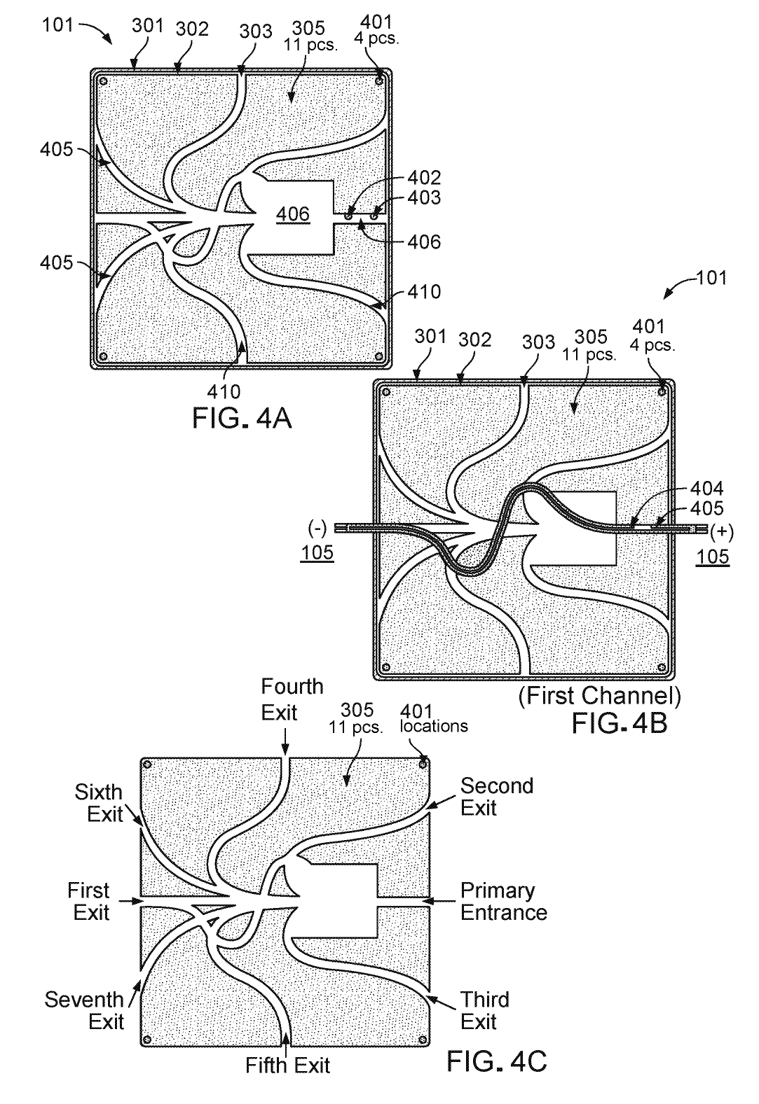

FIG. 3 is an illustration of the front-face of a tile. FIG. 3 shows the edge of the transparent glass or polycarbonate front cover 301, the transparent encapsulant layer 302, the upper layer 303 of the backer board (305 in FIG. 4A), the photovoltaic (PV) cell 304, and four locating pins 401 at each corner. The input wire 103, the output wire 104, and the pass-through wire 105 are also shown. In this example, the tile 101 is formed of multiple layers including the backer board (305 in FIG. 4A), the elastomer encapsulant 302 (e.g., polydimethylsiloxane Sylgard 184 manufactured by Dow Corning), PV cells 304, the UV and abrasion resistant cover 410, and a gasket (not shown).

Once assembled, the elastomer encapsulant 302 encases the PV cells 304 and the UV and abrasion resistant cover 301 surrounds the encapsulant 302 forming a weather resistant assembly. In some instances, all other voids between the transparent front cover 301 and the backer board 304 are also filled with the elastomer encapsulant 302.

In general, the PV cell 304 is an electrical device that converts the energy of light directly into electricity by the photovoltaic effect. The PV cells 304 can be made of various materials including crystalline silicon or polycrystalline silicon. In additional examples, the PV cell 304 can be made from materials such as cadmium telluride, copper indium gallium selenide, gallium arsenide, or indium gallium nitride. The PV cell 304 may include an anti-reflection coating to increase the amount of light coupled into the PV cell 304. Exemplary anti-reflection coatings include silicon nitride and titanium dioxide. The PV cells 304 include a full area metal contact made on the back surface (e.g., the surface nearest to the backer board 305).

The top surface of the tile 101 is made of a UV and abrasion resistant transparent cover 301. In one example, the cover can be made of a glass material. In other examples, cover 301 can be made of a polycarbonate material. In some instances, the tiles are covered in a polycarbonate cover that is transparent and treated to mitigate against degradation from ultraviolet light, and that are uniquely formed with sidewalls extending perpendicularly from the face to protect the tile assembly. Tiles may be covered in other materials performing the same technical role, such as glass, quartz, etc. The use of a polycarbonate material rather than glass provides various advantages. For example, polycarbonate is less likely to shatter or break. UV protective additives and coatings provide long-life in sunny conditions. Additionally, the cost to manufacture a polycarbonate layer can be less than the cost to manufacture a glass layer because the polycarbonate layer can be made using an injection molding process.

In some instances, prior to installation on a wall, the tiles 101 are shipped with adhesive opaque labels. The labels prevent damage to the tiles during construction, and more importantly prevent light from energizing the tiles during installation and creating a safety hazard to installers. The adhesive opaque labels remain until electrical commissioning of the wall system is completed; in one example, removal of the labels is accomplished via a cleaning process that dissolves the labels.

In some examples, the tiles 101 can be initially covered with labels or other degradable surface material that prevents light from reaching the PV cell 304 prior to removal of the material. For example, the surface 101 of the tile 101 can be coated with a label that prevents activation of the PV cell 304 by blocking light from being transmitted through the label (e.g., the label is substantially opaque). By blocking the light from activating the PV cell 304, tiles 101 can be electrically connected to one another without current being present in the wiring (e.g., the cells are not “live”). This simplifies the task of making electrical connections between the tiles because installers do not have to work with live wires (e.g., wires carrying an electrical current) while forming the connections. Additionally, the label can protect the surface of the PV unit from being scratched during transportation and construction (e.g., while the tile units are on and removed from the pallet). After removal of the label the surface of the PV cell, 304 is able to receive light and generate power.

In some examples, the label on the surface of the tile 101 can be formed from a soluble material that can be removed using a masonry cleaning solution. Examples of such biodegradable materials that can be used as a cover include starch-based products, which can be preprinted and applied to the surface of the tile 101 as a label.

In some additional examples, the label on the tile 101 can include an indication of a positive and negative terminal for the tile 101. Providing an indication of the positive/negative terminals can aid in laying the tiles 101 because it will provide a visual indication of the correct orientation of the tile 101. In some additional examples, the portion of the label on the positive side of the tile 101 can be a different color from the portion of the label on the negative side of the tile 101. As such, once the tiles 101 are assembled it will be visually apparent based on the pattern of the labels when a tile 101 is not placed in the planned orientation.

FIGS. 4A and 4B are illustrations of the back-side of a tile without and with, respectively, electrical wiring. FIG. 4A shows wiring removed to expose the cavities 410 inset into the back-side of the backer board 305. The edge of the clear front cover 301 is visible at the outside-edge; adjacent is the transparent encapsulant layer 302. In some instances, the cavities 410 expose a visible portion of the front-layer 303 of the backer-board 305. Pin 401 is one of four locating pins at each corner. Hole 402 is the output wire 104 location from the photovoltaic cell; hole 403 is the input wire 103 location to the photovoltaic cell 304. The PV cells 304 are situated on the front side of the backer board 305. The PV 304 cells are aligned with the backer board 305 using the alignment pins 401.

The backer board 305 forms the rear surface of the tile. The backer board 305 provides various functions for the PV unit 400 including leveling the rough surface of the tile unit below the PV cell 304. Providing a level surface below the PV cells 304 helps to prevent fracturing of the fragile PV cell 304. For example fracturing can occur on application of pressure to the top of the tile unit 101. The backer board 305 also provides a surface to which other layers of the tile unit 101 are adhered to form an enclosed unit that is resistant to moisture, oxygen, or other contaminants that may damage the PV cell 304. The backer board 305 can also serve as a thermal sink to help transfer heat and potentially reduce high operating temperature of the PV cell 304 that may reduce its performance and longevity.

The backer board 305 can be formed of various materials including cement board, which is a combination of cement and reinforcing fibers. When used, cement board adds impact resistance and strength to the tile unit 101. In some examples, the backer board 305 is made from a Portland cement based core with glass fiber mat reinforcing at both faces. In some examples, the backer board 305 is made of glass.

The backer board 305 includes alignment pins 401 that are raised from the surface of the backer board 305. The alignment pins 401 are used to position and hold the PV cell 304 at an appropriate location on the PV facing side 303 of the backer board 305. The alignment pins 401 have a height calibrated to space the abrasion resistant cover 301 apart from the PV cell 304. In some examples, the pins 401 have a height between 1 mm to 4 mm. The length of these pins forms a defined thickness between the PV cell 304 and the clear cover 301. The alignment pins 401 contact the clear cover 301 such that impact forces applied to cover 301 are predominately transferred to the backer board 305 rather than through the PV cell 304. Transferring of forces from cover 301 (e.g., from the surface of the PV unit) to the backer board 305 can prevent damage to the relatively fragile PV cells 304.

FIG. 4B shows a default wiring pattern with power 404, 405 and pass-though wiring 105 set into a serpentine channel 410. The power-conductor wire 404, 405 and pass-through wire 105 are bundled together as a two-wire pair. The pass-through wire 105 continues entirely through the tile 101. The serpentine path of the cavities 410 is necessary to create equal-length options for wiring to each of seven (7) possible positions of subsequent tiles, each of which are shown in FIGS. 5A-5G. The backer-board 305 cavity 406 between locations 404 and 405 is sufficiently sized to house a bypass diode as needed for individual field applications.

The pass-through wire 105 is located between the encapsulant and the backer board 305. In some examples, the pass-through wire 105 is secured to the backer board 305 using epoxy. The pass-through wire 105 is configured to pass energy through the tile, but is not connected to the PV cell 304 of the particular tile. The pass-through wire 105 serves as a return for a set of connected tiles to enable electrical design flexibility in individual applications. As such, both the individual wiring for the tile 103, 104 and the pass-through wiring 105 are placed in the serpentine channel 303 in the backside of the backer board 305.

For east of description, FIG. 4C identifies the various channel entrances are exits corresponding to the named channels of FIGS. 4B and 5A-5G.

FIGS. 5A-5G show each of the paths that pass-through wiring can take through the equal-length channels. Each of the FIGS. 5A through 5G outlines the internal wiring paths corresponding to the relative tile 101 positions shown in FIG. 1. Additionally, FIG. 5D depicts the case where the tile 101 may be used to cache a splice connector 505 in a square cutout area 504 providing space for a butt-style connector 505 suitable for direct burial. The square cutout area 504 or cavity is intentionally located where a splice can be made whatever path the wiring subsequently takes to the next tile 102.

The physical channels 410 in the backer board are designed to route the connecting wiring to each possible location in a manner that requires the same length of wire to reach that location.

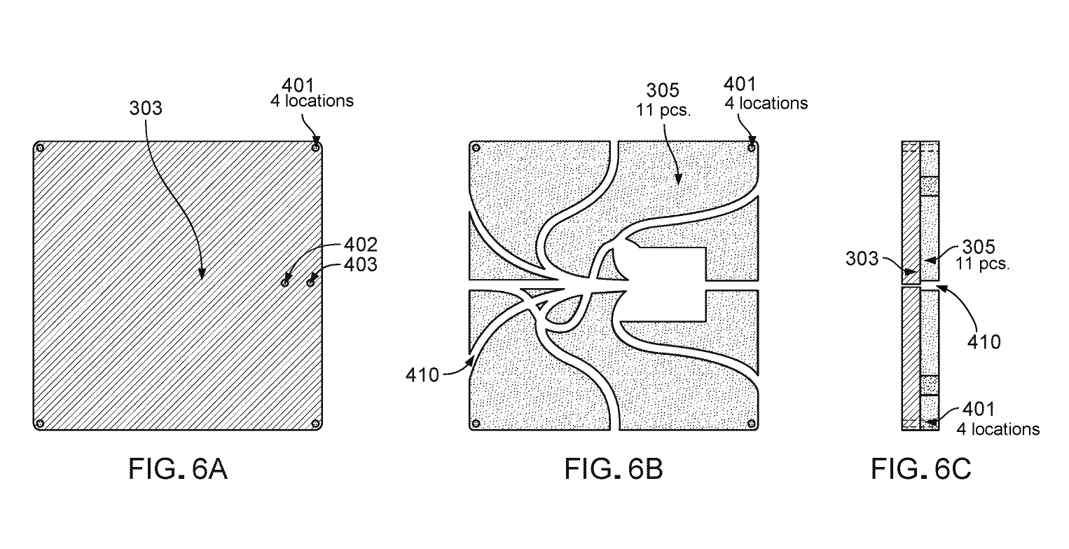

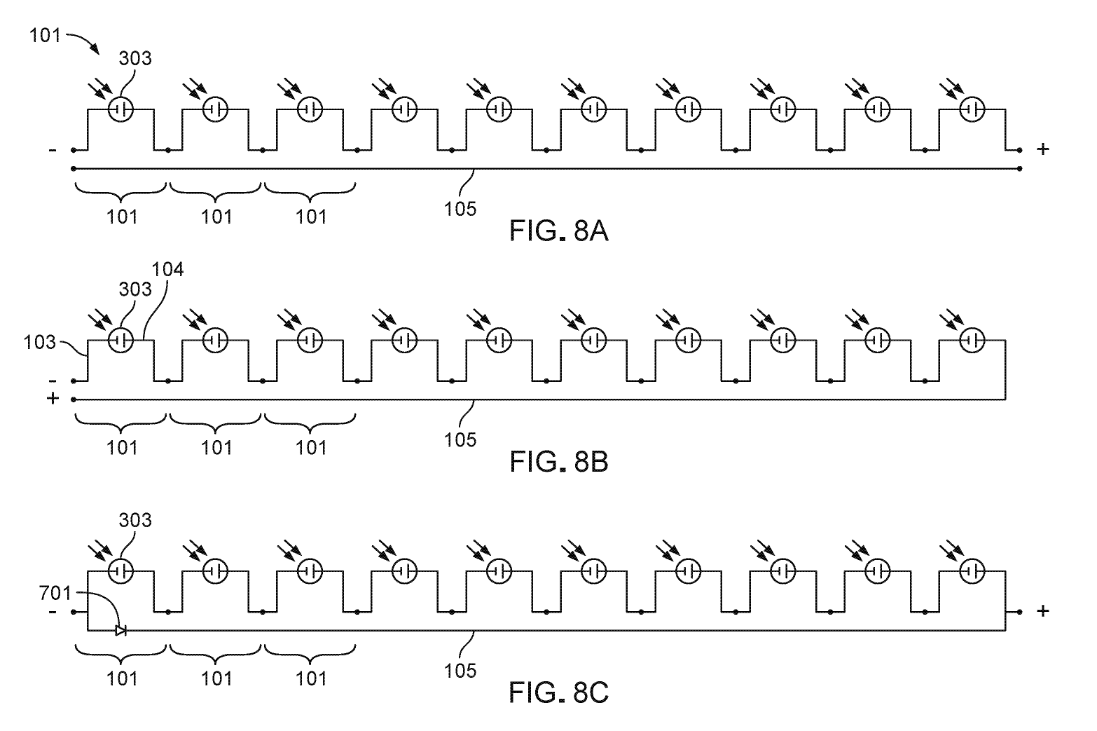

FIGS. 6A-6C are front, rear, and side illustrations, respectively, of the backer board. FIG. 6 depicts the two layers 303, 305 of the backer-board. In one example, the board 305 is a cast mixture of Portland cement and other binders; the front layer 303 is a single piece that forms the structural base of the tile 101 while also holding the photovoltaic cell 304 in place via locator pins. FIG. 6B shows the back layer 305 is an 11-piece set of elements that form the wiring and interconnection cavities 410. FIG. 6C shows a side view of the assembled backer board pieces 303, 305. In some examples, the front 303 and back 305 are bonded or cast as a single piece. In other examples, the two pieces 303, 305 are separate and affixed in the field in order to provide for inspection of all interconnection points in the installation prior to covering. In this case, the back layer 305 is installed onto the wall with the rest of the tile 101; the connections are made, and the front-layer 303, encapsulant 302, photovoltaic-cell, 304 and polycarbonate cover 301 assembly is affixed afterward. In this case, wiring 103,104,105 is connected via male-female lug terminals.

At the locations where the wiring exits the last tile in a string, the exit wire is connected in the tile cavity with a splice connector and wired into a wall penetration to the interior of the building, where it is connected to conventional solar PV junction box, AC inverter, or DC battery system.

Electrical Design

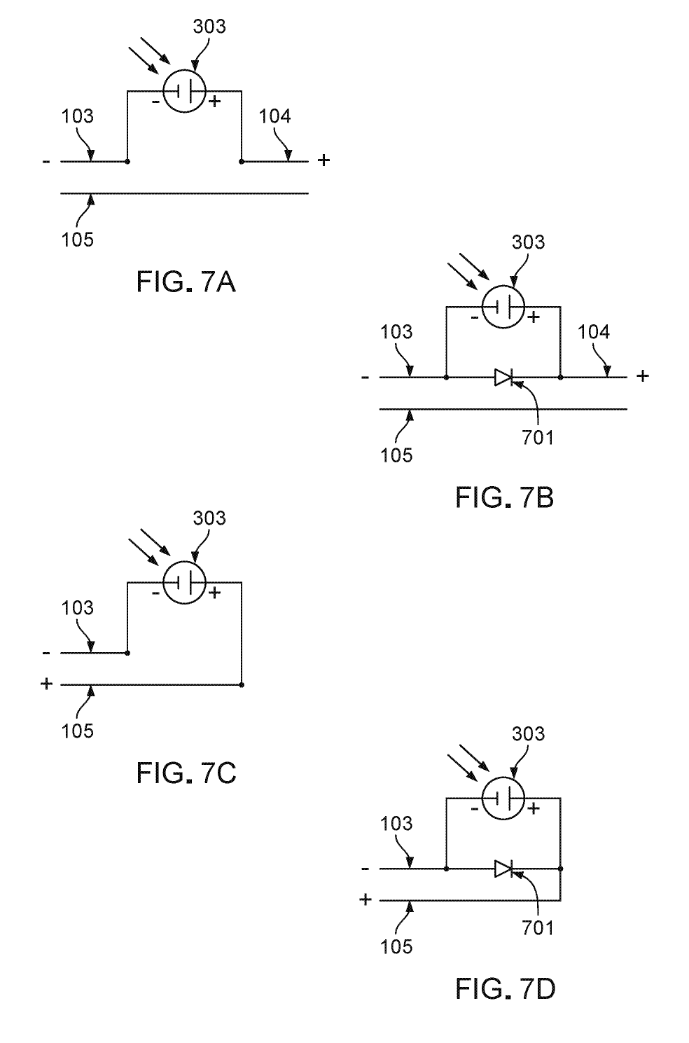

FIGS. 7A-7D are schematics of various wiring options for a single tile. The electrical schematics of various wiring options for a single tile are shown in FIG. 7A-7D, with input lead (−) 103, output lead (+) 104, photovoltaic cell 304, pass-through wire 105, and diode 701. FIG. 7A shows a tile 101 with conventional power wiring and no bypass diode. FIG. 7B shows the same wiring with a bypass diode added. FIG. 7C shows a cell 304 with the output 104 wired to the pass-through wire 105; FIG. 7D shows the same wiring as FIG. 7C, but with a bypass diode 701 added.

Table 1 below lists the electrical characteristics of an example single tile 101, based on typical single cell electrical parameters of an example photovoltaic cell 304 manufacturer. In this example, a single tile 101 is nominally rated at 3.5 Watts, generating 6 Amps at 0.58 Volts.

For a 30-tile string contained in a single box of tiles 101, nominal electrical performance is provided in Table 2. For a single tile 101 at maximum rated power, current is nominally 6 Amps and voltage is 0.58 Volts. Per 30-tile string, nominal maximum current is the same as for a single cell 304 at 6.0 Amps. Voltages in series connections are additive, so the 30-tile voltage at maximum power is 17.5 Volts. Thus, for the 30-tile string, the maximum DC power is 17.5 Volts×6.0 Amperes=105 Watts.

TABLE 1
Electrical characteristics of a single tile.

| Electrical Performance | Value | Units |
|---|---|---|
| Nominal Power (Pnom) | 3.5 | Watts |
| Average Efficiency (%) | 21% | Percent |
| Rated Voltage (Vmpp) | 0.58 | Volts |
| Rated Current (Impp) | 6.0 | Amps |
| Maximum System Voltage | 600 | Volts |
| Maximum Series Fuse | 20 | Amps |

TABLE 2
Electrical characteristics of a 30-tile string.

| Electrical Performance | Value | Units |
|---|---|---|
| Nominal Power (Pnom) | 105 | Watts |
| Average Efficiency (%) | 21% | Percent |
| Rated Voltage (Vmpp) | 17.5 | Volts |
| Rated Current (Impp) | 6.0 | Amps |
| Maximum System Voltage | 600 | Volts |
| Maximum Series Fuse | 20 | Amps |

In the example configuration, the tiles 101 are set at nominal 152 mm (6-inch) distances center-to center, or 4 tiles 101 per square foot. The maximum power on an area basis is 150 Wattsₚₑₐₖ DC per square meter (14 Wattsₚₑₐₖ DC per square foot). For a 3 meter high (10-ft. high) wall section, maximum power is calculated to be 140 Wattsₚₑₐₖ DC per horizontal linear foot).

FIGS. 8A-8C are electrical schematics of three different strings of 10 tiles. FIG. 8A illustrates a 10-tile string as it would be installed “out-of-the box.” FIG. 8B illustrates how the pass-through wiring 105 is used to close a circuit within the tiles 101. FIG. 8C shows how the pass-through wiring 105 may be used to provide bypass-diode 701 circuitry for the ten tile group. These wiring options can be accomplished using the cavities and equal-length wiring channels 410 shown in FIG. 4.

Field Installation

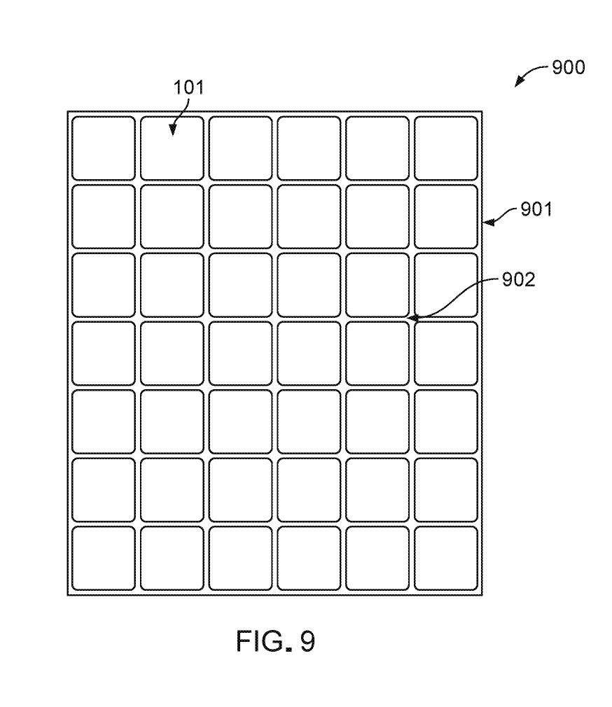

FIG. 9 shows an example photovoltaic tile system 900 wall installation. The tiles 101 are cemented to the wall 901 and grouted between joints 902. There are no connectors visible. Tiles 101 are installed as full tiles or cut pieces. Tiles 101 can be installed in block fashion as shown or staggered per row. Cut pieces may be included in a finished wall system but are not be wired to produce electricity.

Proper design to address construction requirements and practices is integral to the photovoltaic tile system. Sets of tiles 101 are shipped to the installer in multiple-tile sets. In one example, 30 tiles 101 are shipped together. The wiring paths in the pre-wired tiles are factory pre-set for linear placement; repositioning the back-side wiring is typically needed only for interconnections to higher or lower courses; on a larger-wall, the multiple-tile strings can be installed almost as easily as conventional tiles.

Field splices will be required at 30-tile intervals or due to customer design. Similar to solar masonry systems, separation of tasks required of tile-installers and electricians can be accomplished. For tile 101, at each location where there is a splice, that top section of any tile 101 can be separated from the bottom section to permit access for the electrician. The separation is possible at the joint between the upper backer board 303 and lower backer board 305. The upper backer board 303 wiring is attached to the lower section 305 wiring via two male-female quick connect terminals. After the electrician has completed the splices (and the local electrical inspector has inspected those splices), then the tile installer cements the top sections of the connector tiles to the lower section and grouts the wall.

In some instances, photovoltaic tiles 101 are pre-wired, 30 tiles at a time. The negative terminal of each tile 101 is pre-wired at a fixed connection point; the positive terminal is prewired at a connection point that allows wiring to the adjacent tile to be re-routed from a side-by-side location to other locations adjacent to it: directly above, directly below, staggered above, or staggered below the relative position of the current tile.

In some cases, the connecting wire 103, 104, 105 used on the back of the backer board 305 is rated for direct concrete burial for photovoltaic applications, and is composed of two separate conductors—one for connecting each of the tiles 101 in series and one for pass-through wiring where needed.

In some instances, each tile 101 is provided with an installation cavity 406 for a bypass diode 701 that enables the circuit to continue if the photovoltaic element 304 is disabled. Inclusion of a bypass diode 701 is dictated by the individual field application; wall areas near ground or other possible shading may be fitted with diodes; areas in upper building levels clear of possible shading may not.

In the case where a wire splice must be made, the channel 504 in the back of the backer board 305 provides sufficient cavity space for an appropriate splice connector 505. The splice can connect a string of tiles 101, an end-conductor to a set of tiles 101, or a splice to the pass-through wire 105, as needed per individual application. Where a splice is made, that individual tile 101 can be identified by a small mark to aid in later maintenance of the installation if needed.

What is claimed is:

1. A photovoltaic-clad tile unit comprising:
a rigid support structure with a back surface and comprising a backer board, the back surface defining a plurality of equal-length wiring channels in the rigid support structure and a pass-through channel extending across the tile in a straight line; and
one or more photovoltaic cells supported by the rigid support structure.

2. The photovoltaic-clad tile unit of claim 1, wherein plurality of equal-length wiring channels are configured such that adjacent wiring channels between adjacent photovoltaic-clad tile units are provided.

3. The photovoltaic-clad tile unit of claim 1, wherein each of the plurality of equal-length wiring channels extends from a first edge to one of: the first edge, an opposite edge, or a first or second adjacent edge of the backer board.

4. The photovoltaic-clad tile unit of claim 3, wherein the plurality of equal-length wiring channels is a group of seven equal-length wiring channels.

5. The photovoltaic-clad tile unit of claim 4, wherein each of the group of seven equal-length wiring channels extends from a primary entrance in the first edge of the backer board to one of a corresponding seven exits in the edges of the backer board, the group of seven equal-length wiring channels comprising:
a first channel extending across the tile to a first exit in the opposite edge;
a second channel extending to a second exit in the first edge;
a third channel extending to a third exit in the first edge;
a fourth channel extending to a fourth exit in first adjacent edge;
a fifth channel extending to a fifth exit in the second adjacent edge;
a sixth channel extending to a sixth exit in the opposite edge; and
a seventh channel extending to a seventh exit in the opposite edge.

6. The photovoltaic-clad tile unit of claim 5 wherein the primary entrance and the first, fourth and fifth exits are located in the approximate center of their respective edges, and wherein the second and third exits are located at a same distance from the primary entrance, and the sixth and seventh exits are located at the same distance from the first exist.

7. The photovoltaic-clad tile unit of claim 5, wherein the pass-through channel extends across the file in a straight line from the primary entrance to the first exit.

8. The photovoltaic-clad tile unit of claim 1, further comprising an adhesive layer disposed on the back surface of the tile, the adhesive layer being configured to secure the photovoltaic-clad tile unit to a structure.

9. The photovoltaic-clad tile unit of claim 1, wherein the photovoltaic tile unit further comprise a pass though wire adhered to the back surface of the backer board in one of the plurality of equal-length wiring channels or the pass through channel, the pass though wire electrically isolated from the one or more PV cells.

10. The photovoltaic-clad tile unit of claim 1, wherein the rigid support structure comprises defines an input opening and an output opening, the opening providing an electrical connection to the one or more photovoltaic cells.

11. The photovoltaic-clad tile unit of claim 10, wherein the photovoltaic tile unit further comprises a power-conductor wire adhered to the back surface of the backer board in one of the plurality of equal-length wiring channels or the pass through channel, the power-conductor wire comprising a input wire in electrical connection with the one or more photovoltaic cells via the input opening and an output wire in electrical connection with the one or more photovoltaic cells via the output opening.

12. The photovoltaic-clad tile unit of claim 10, wherein the back surface defines a cavity between the input and output opening, the cavity sized and positioned to house a bypass diode.

13. The photovoltaic-clad tile unit of claim 1, wherein the back surface defines a cutout sized and positioned to house a connector.

14. The photovoltaic-clad tile unit of claim 1, wherein the backer board includes alignment devices that are raised from the surface of the backer board.

15. The photovoltaic-clad tile unit of claim 1, further comprising a transparent cover disposed above the one or more photovoltaic cells and configured to be secured to the rigid support structure to provide a protective enclosure that encloses the one or more photovoltaic cells.

16. The photovoltaic-clad tile unit of claim 15, wherein the photovoltaic unit further comprises an opaque removable label adhered to an outer surface of the cover.

17. The photovoltaic-clad tile unit of claim 16, wherein the label comprises a pre-printed label made of a dissolvable material.

18. The photovoltaic-clad tile unit of claim 16, wherein the label includes a first indicator indicative of the location of the positive terminal and a second indicator indicative of the location of the negative terminal.

19. The photovoltaic-clad tile unit of claim 1, wherein the cover comprises a polycarbonate or glass cover and the cover includes a top surface and sidewalls extending approximately perpendicular to the top surface.

20. The photovoltaic-clad tile unit of claim 1, wherein the photovoltaic-clad tile unit further comprises a gasket.

21. The photovoltaic-clad tile unit of claim 1, wherein the photovoltaic-clad tile unit is configured to be electrically connected to other photovoltaic-clad tile units to form a photovoltaic array.

22. The photovoltaic-clad tile unit of claim 1, wherein the backer board comprises cement and reinforcing fibers.

23. The photovoltaic-clad tile unit of claim 1, wherein the backer board comprises a Portland cement based core with glass fiber mat reinforcing.

24. A method of installing a photovoltaic-clad tile unit, the method comprising,
given a photovoltaic-clad tile unit comprising upper and lower backer board layers, the upper backer board layer comprising a photovoltaic cell, and the lower backer board layer having a first side positioned against the upper backer board layer and an opposite side;
adhering the opposite side of the lower backer board layer to a surface;
removing the upper backer board layer from the lower backer board layer;
disconnecting the photovoltaic cell of the upper backer board layer from a wire positioned in a first channel of the lower backer board layer;
changing at least one of the wire entrance position and wire exit position by repositioning the wire lower backer board layer from the first wire channel to a second wire channel; and
reconnecting the photovoltaic cell of the upper backer board layer to the wire by replacing the upper backer board layer on the lower backer board layer.

25. A method of installing a photovoltaic-clad tile unit, the method comprising,
given a first and second photovoltaic-clad tile units being coupled together by the wire in a first adjacent orientation and each comprising a backer board defining a plurality of equal-length wiring channels, each of the equal-length wiring channels corresponding to an adjacent orientation of the first and second photovoltaic-clad tile units, and the wire being positioned in a first channel of the plurality of channels in each of the first and second units;
removing the wire from the first channel of the plurality of equal-length wiring channels of the first photovoltaic-clad tile unit;
positioning the first and second photovoltaic-clad tile units in a second adjacent orientation; and
placing the wire in a second channel of the plurality of equal-length wiring channels of the first photovoltaic-clad tile unit, the second channel corresponding to the second adjacent orientation of the first and second photovoltaic-clad tile units.
